(19) United States
(12) Patent Application Publication
(10) Pub. No.: US 2016/0365493 A1
(43) Pub. Date: Dec. 15, 2016

(54) LIGHT-EMITTING DIODE DEVICE

(71) Applicant: LEXTAR ELECTRONICS CORPORATION, Hsinchu (TW)

(72) Inventors: Hsin-Lun SU, Chiayi County (TW); Chih-Hao LIN, Taipei City (TW); Fang-Chang HSUEH, Taichung City (TW); Tzong-Liang TSAI, Taichung City (TW); Yi-Jyun CHEN, Chiayi County (TW)

(21) Appl. No.: 15/054,065

(22) Filed: Feb. 25, 2016

(30) Foreign Application Priority Data
Jun. 10, 2015 (TW) 104118712

(51) Int. Cl. H01L 33/56

(52) U.S. Cl. CPC H01L 33/56

(57) ABSTRACT

A light-emitting diode device includes a shell with a recess, wherein the shell does not contain metal oxide. A plurality of lead frames extends from the bottom of the recess to the outside of the shell. At least an UV light-emitting diode (LED) chip is disposed on the bottom of the recess and is electrically connected to the lead frames, wherein the UV LED chip has a wavelength range of 200 nm-400 nm. In addition, an encapsulation adhesive fills the recess to cover the UV LED chip.

### CROSS REFERENCE TO RELATED APPLICATIONS

This Application claims priority of Taiwan Patent Application No.104118712, filed on Jun. 10, 2015, the entirety of which is incorporated by reference herein.

### BACKGROUND OF THE INVENTION

### Field of the Invention

The present invention relates to a light-emitting diode, and in particular to an UV light emitting diode package having high efficiency.

### Description of the Related Art

UV light-emitting diode packages have excellent utilities in antibiosis, dust proof, sterilization, purification and some similar functions. Further, the UV light-emitting diodes have advantages in small volume, long lifetime, low power consumption, etc. Therefore, the application field of the UV light emitting diode packages has been expanded to household appliances, for example, air purifier, water purifier, refrigerator, air conditioner, dishwasher, medical instruments and some similar objects. The UV light-emitting diodes have become required devices for life.

Many factors affect the lifetime of the UV light-emitting diodes, for example, the emission wavelength of the UV light-emitting diodes, the temperature of the operation environment and humidity or other factors impact that whether the UV light-emitting diodes degrade after using for a long time. However, the UV light-emitting diodes that using conventional packaging technology often have problems in short lifetime.

Therefore, there is a need for UV light-emitting diode package structures which have simple, low cost, high productivity and long lifetime.

### BRIEF SUMMARY OF THE INVENTION

The disclosure provides light-emitting diode devices to apply for an UV light-emitting diode chip. The light-emitting diode devices include a shell which does not contain a metal oxide compound. Therefore, it can avoid yellowing of the shell and the lifetime of the light-emitting diode device is thereby increased.

The disclosure provides a light-emitting diode device comprising a shell with a recess, wherein the shell does not contain a metal oxide compound. A plurality of lead frames extends from a bottom surface of the recess to an outer surface of the shell. At least an UV light-emitting diode chip is disposed on the bottom surface of the recess and electrically connected to the lead frames, wherein the UV light-emitting diode chip has an emission wavelength in a range of 200 nm-400 nm. In addition, an encapsulation adhesive fills the recess to cover the UV light-emitting diode. The shell does not contain the metal oxide compound which absorbs an UV light generated by the UV light-emitting diode chip, thereby reducing the UV light absorption of the shell, light attenuation of the light-emitting diode device and yellowing of the shell.

### BRIEF DESCRIPTION OF THE DRAWINGS

The present invention can be more fully understood by reading the subsequent detailed description and examples with references made to the accompanying drawings, wherein:

FIG. 1 shows a perspective view of a light-emitting diode device according to some embodiments of the disclosure.

FIG. 2 shows a cross section view of a light-emitting diode device according to some embodiments of the disclosure.

### DETAILED DESCRIPTION OF THE INVENTION

The following detailed description is a package structure of a light-emitting diode device. In the following detailed description, for purposes of explanation, numerous specific details are set forth in order to provide a thorough understanding of the disclosed embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. The formation of a first material layer over or on a second material layer in the description that follows may include embodiments in which the first and second material layer are formed in direct contact, and may also include embodiments in which additional material layer may be formed between the first and second material layer, such that the first and second material layer may not be in direct contact.

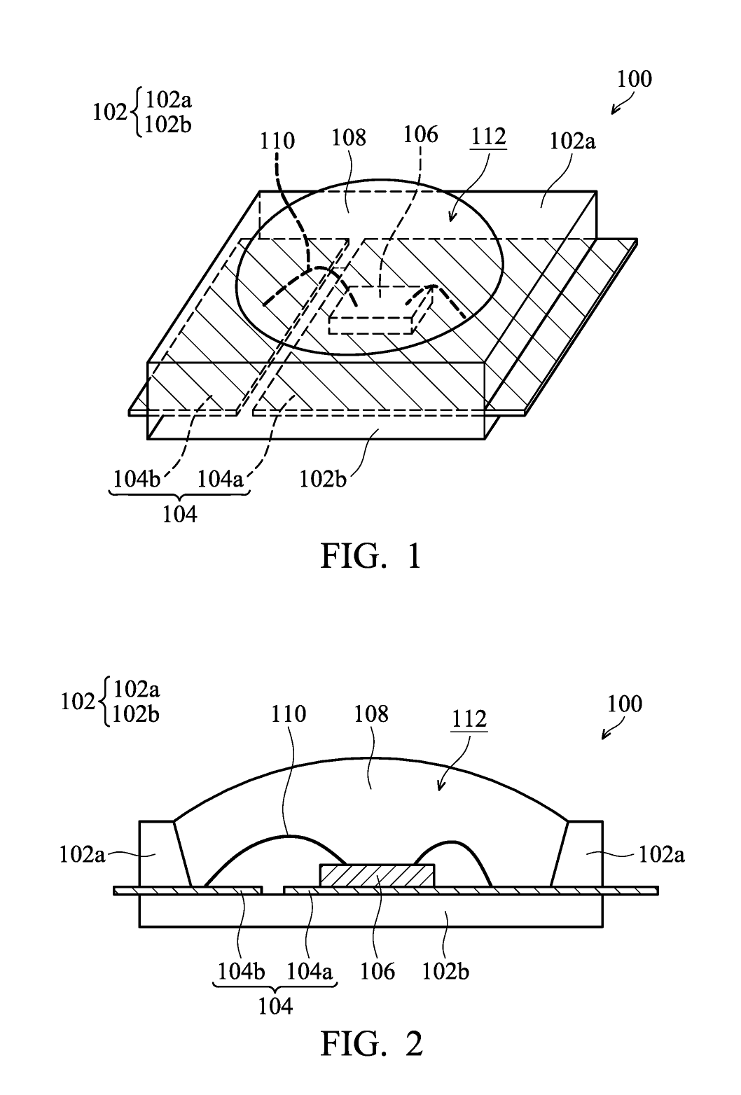

As shown in FIGS. 1-2, FIG. 1 shows a perspective view of a light-emitting diode device 100 according to some embodiments of the disclosure. FIG. 2 shows a cross section view of the light-emitting diode device 100 according to some embodiments of the disclosure. In some embodiments, the light-emitting diode device 100 may be a plastic leaded chip carrier (PLCC) with lead frames which includes a shell 102 that does not contain a metal oxide compound absorbing UV light. The shell 102 has a recess 112 therein. A UV light-emitting diode chip 106 is disposed on a bottom surface of the recess 112. A plurality of lead frames 104 extends from the bottom surface of the recess 112 to an outer surface of the shell. The UV light-emitting diode chip 106 is electrically connected to a bonding wire 110 of the lead frames 104.

In some embodiments, the UV light-emitting diode chip 106 has an emission wavelength in a range of 200 nm-400 nm. The UV light-emitting diode chip 106 is used as a light source of the light-emitting diode device 100. Although FIG. 1 only shows one UV light-emitting diode chip 106, it is only the purpose for simplicity and not limited thereto. In some embodiments, the light-emitting diode device 100 may include two or more UV light-emitting diode chips 106. In some embodiments, the configuration of the UV light-emitting diode chips 106 are, for example, a horizontal chip, a vertical chip or a flip chip.

Although FIGS. 1-2 don't show the detailed structure of the UV light-emitting diode chips 106, generally, the UV light-emitting diode chip 106 includes a first type semiconductor layer, an active layer, a second type semiconductor layer, a first electrode electrically connecting to the first type semiconductor layer and a second electrode electrically connecting to the second type semiconductor layer which are formed in order. The active layer is located on the first type semiconductor layer, and the second type semiconductor layer is located on the active layer. The active layer includes a layer of multiple quantum well, such as GaN or GaP based materials or similar materials. The first type semiconductor layer can be a nitride semiconductor layer doped with n type dopants, for example, an n type GaN layer. The second type semiconductor layer may be a nitride semiconductor layer doped with p type dopants, for example, a p type GaN layer. The first electrode may be a p type electrode and the second electrode may be an n type electrode. In some embodiments, the first and the second electrodes (not shown) can be formed on a top surface of the UV light-emitting diode chip 106.

The UV light-emitting diode chip 106 is attached to the bottom surface of the recess 112 of the shell 102 by a die bond paste. The UV light-emitting diode chip 106 can be attached on the lead frames 104 directly, and the UV light-emitting diode chip 106 can be electrically connected to the lead frames 104 by a bonding wire 110. The Lead frames 104 includes a first portion 104a and a second portion 104b separated from the first portion 104a. In some embodiments, the UV light-emitting diode chip 106 is, for example, a vertical chip disposed on the first portion 104a of the lead frames 104. One electrode (not shown) of the UV light-emitting diode chip 106 directly contacts with the first portion 104a and then electrically connects to the lead frames 104. Further, the other electrode (not shown) of the UV light-emitting diode chip 106 electrically connects to the second portion 104b by the bonding wire 110. In some embodiments, as shown in FIGS. 1-2, the UV light-emitting diode chip 106 is, for example, a horizontal chip disposed on the first portion 104a of the lead frames 104. Both electrodes of the UV light-emitting diode chip 106 electrically connect to the first portion 104a and the second portion 104b respectively, by two bonding wires 110. In some embodiments, the UV light-emitting diode chip 106 is, for example, a flip chip disposed on both the first portion 104a and the second portion 104b simultaneously. The two electrodes of the UV light-emitting diode chip 106 electrically connect to the first portion 104a and the second portion 104b respectively by solder balls (not shown).

The lead frame 104 is located at the bottom of the recess 112 of the shell 102, and interposed between an upper part 102a and a lower part 102b of the shell 102. The lead frame 104 further extends from the bottom of the recess 112 to the outside of the shell 102 to connect with an external circuit (not shown). When an external the electrical energy transmits to the UV light-emitting diode chip 106 through the first portion 104a and second portion 104b of the lead frame 104, the UV light-emitting diode chip 106 converts the electrical energy into light energy and then illuminates.

Because a portion of the electrical energy and a portion of the light energy is converted to heat energy in the interior of the UV light-emitting diode chip 106, the material of the lead frames 104 is preferably selected from materials having good thermal and electrical conductivity, such as metal. The lead frames 104 provide the path for current transmission of the UV light-emitting diode chip 106 and the ways for dissipating the heat generated from the use of the UV light-emitting diode chip 106. In some embodiments, a layer of metal, such as gold or silver, may be deposited on a surface of the lead frames 104 for enhancing the reflectivity. Therefore, luminous intensity of the UV light-emitting diode chip 106 is improved. Said deposition process can be, for example, electroplating, sputtering, resistive heating evaporation, electron beam evaporation, or any other suitable deposition method.

The shell 102 is functioned as a support of the lead frames 104. The shell 102 can have any shapes and is formed of insulating materials. Plastic package supports of conventional light-emitting diode devices usually contain titanium dioxide (TiO₂) for enhancing the reflectivity of the plastic package support and the luminescent efficiency of the light-emitting diode device. However, the UV light absorption of TiO₂ is much greater than visible light absorption. Therefore, if the plastic package support contains TiO₂, the luminescent efficiency of the UV light-emitting diode devices will be decreased and the light attenuation will be generated due to the UV light absorption of the TiO₂. In addition, yellowing of the plastic package support containing TiO₂ occurs due to the UV light absorption of the TiO₂ and then impacts the service life of the products. In order to solve the above problems occurring in the current technique, some embodiments of the disclosure provide a shell that does not contain a metal oxide compound which absorbs UV light to be used in the UV light-emitting diode device.

In some embodiments, the shell 102 may be a transparent shell to reduce the reflection of the shell 102 which is generated by the colors of the shell 102. The reflection of the shell 102 will induce light attenuation of the UV light-emitting diode chip 106. In some embodiments, the material of the shell 102 is such as epoxy molding compound (EMC), silicon molding compound (SMC), fluororesin, transparent ceramic or glass without TiO₂. In some embodiments, the material of the shell 102 is cyclopolymerization of perfluoro (CYTOP).

An encapsulation adhesive 108 for lens fills in the recess 112 to cover the UV light-emitting diode chip 106 and the bonding wire 110, such that the UV light-emitting diode chip 106 is isolated from the outer environment. The encapsulation adhesive 108 for lens can be a transparent colorless paste. The material of the encapsulation adhesive 108 fills may be silicone, epoxy resins, poly(methyl methacrylate (PMMA), polycarbonate (PC) or glass.

TABLE 1

| Sample | Material | Luminous power (mW) |
|---|---|---|
| A | EMC without TiO₂ | 50.01 |
| B | EMC contaning TiO₂ | 35.18 |
| C | SMC contaning TiO₂ | 36.89 |

Table 1 shows that the luminous power comparison of the light-emitting diode device 100 while the emission wavelength of the UV light-emitting diode chip 106 is 385 nm and the shell is made of the samples A, B, C respectively. The shell of the sample A is epoxy molding compound (EMC) without TiO₂, the shell of the sample B is epoxy molding compound (EMC) containing TiO₂, and shell of the sample C is silicon molding compound (SMC) containing TiO₂. As shown in Table 1, the luminous power of the sample A is 50.01 mW, the luminous power of the sample B is 35.18 mW and the luminous power of the sample C is 36.89 mW. It shows that the luminous power of the light-emitting diode device using the shell without TiO₂ is much greater than the luminous power of the light-emitting diode device using the EMC or SMC shell containing TiO₂. Therefore, using the shell without TiO₂ reduces more UV light absorption than that of the shell containing TiO₂. Further, it reduces light attenuation of the light-emitting diode device and prevents yellowing of the shell.

According to the embodiments of the disclosure, the light-emitting diode devices use the shell without metal oxide compound which absorbs UV light. Thus, the shell absorbs less UV light generated by the UV light-emitting diode chip. Further, it reduces light attenuation of the light-emitting diode device and prevents yellowing of the shell. Therefore, the effects of high efficiency, high luminance and high service life of the light-emitting diode device are achieved.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A light-emitting diode device, comprising:
a shell having a recess, wherein the shell does not contain a metal oxide compound;
a plurality of lead frames extending from a bottom surface of the recess to an outer surface of the shell;
at least an UV light-emitting diode chip disposed on the bottom surface of the recess and electrically connected to the lead frames, wherein the UV light-emitting diode chip has an emission wavelength in a range of 200 nm-400 nm; and
an encapsulation adhesive filled in the recess to cover the UV light-emitting diode, thereby reducing the UV light absorption of the shell, light attenuation of the light-emitting diode device and yellowing of the shell.

2. (canceled)

3. The light-emitting diode device 1, wherein the shell is transparent to reduce a light reflection and a light attenuation.

4. The light-emitting diode device 3, wherein the material of the shell comprises an epoxy molding compound, silicon molding compound, ceramic or glass.

5. The light-emitting diode device 4, wherein the material of the shell is a cyclopolymerization of perfluoro.

6. The light-emitting diode device 1, wherein the surfaces of the lead frames are coated with a gold or a silver layer.
